(19) United States
(12) Patent Application Publication
(10) Pub. No.: US 2006/0214187 A1
(43) Pub. Date: Sep. 28, 2006

(54) Wafer for semiconductor device fabrication, method of manufacture of same, and field effect transistor

(75) Inventors: Juro Mita, Tokyo (JP); Hideyuki Okita, Tokyo (JP); Fumihiko Toda, Tokyo (JP)

Correspondence Address: VENABLE LLP, P.O. BOX 34385, WASHINGTON, DC, 20045-9998, US

(73) Assignee: Oki Electric Industry Co., Ltd., Tokyo (JP)

(21) Appl. No.: 11/378,324

(22) Filed: Mar. 20, 2006

(30) Foreign Application Priority Data
Mar. 25, 2005 (JP) 2005-087650

(51) Int. Cl. H01L 29/739; H01L 21/336

(52) U.S. Cl. 257/194; 438/285; 257/E29.246

(57) ABSTRACT

A wafer for semiconductor device fabrication, from which large output power can be obtained by making the off-state breakdown voltage higher than in the prior art. The wafer for semiconductor device fabrication comprises a substrate, GaN electron transit layer formed on the side of the principal surface of the substrate, and AlGaN electron supply layer formed on the electron transit layer. The thickness of the electron transit layer is from 0.2 to 0.9 μm.

### BACKGROUND OF THE INVENTION

1. Field of the Invention

This invention relates to a wafer suitable for use in semiconductor device fabrication, method of manufacturing a wafer, and a field effect transistor.

2. Description of Related Art

Gallium nitride semiconductors (hereafter “GaN semiconductors”) have properties of a high dielectric breakdown voltage and high saturation electron velocity. HEMTs (high-speed mobility transistors) comprising AlGaN/GaN heterostructures, which utilize these properties, are attracting attention as high-speed devices to replace GaAs semiconductor devices.

At present, GaN single-crystal substrates are extremely expensive. Hence GaN semiconductors are formed on substrate such, for example, as SiC substrates or sapphire substrates, which are extremely inexpensive and have lattice constants close to those of GaN. Instances of fabrication of GaN semiconductors on more easily obtained Si substrates have also been reported in the literature (“MOCVD growth of GaN films and AlGaN/GaN hetero-structures on 4-inch Si substrates”, Hiroyasu Ishikawa et al, Technical Report of IEICE, ED2003-149, CPM2003-119, LQE2003-67 (2003-10), Vol. 103, No. 342, pp. 9-13).

FIG. 10 shows a conventional GaN HEMT, fabricated on semi-insulating SiC substrate. FIG. 10 is a cross-sectional view of a HEMT.

According to FIG. 10, a buffer layer 102 of AlN is formed to a thickness of 10 to 200 nm on the semi-insulating SiC substrate 101. On the buffer layer 102 is formed, to a thickness of 2 to 3 μm, an electron transit layer 104 of GaN, not doped with impurities (hereafter “undoped”). On the electron transit layer 104 is formed an undoped AlGaN electron supply layer 106, to a thickness of 10 to 40 nm. A two-dimensional electron layer 105 is formed on the electron transit layer 104 in proximity to (within approximately 10 nm of) the heterointerface between the electron transit layer 104 and the electron supply layer 106. On the electron supply layer 106 is formed a GaN cap layer 108 to a thickness of 1 to 40 nm. A source electrode 110 and drain electrode 112 are then formed as Ohmic junctions with the cap layer 108. Between the source electrode 110 and drain electrode 112 is formed a gate electrode 114, as a Schottky junction with the cap layer 108. In order to electrically isolate this HEMT 100 from other adjacent devices, element isolation layers 116, 116 extending to a deeper depth than the interface between the electron supply layer 106 and electron transit layer 104 are formed.

In the HEMT 100, by applying a signal voltage to the gate electrode 114, an amplified output power is obtained from the drain electrode 112.

In the prior art, the electron transit layer 104 was required to be of thickness 2 to 3 μm. This was in order to resolve the problem of numerous lattice faults introduced into the electron transit layer 104, arising from lattice mismatch between the SiC substrate 101 and the electron transit layer 104 (GaN). That is, in order to alleviate crystal faults and obtain an electron transit layer 104 with satisfactory crystallinity, it was thought necessary that the thickness of the electron transit layer 104 be of approximately this thickness (2 to 3 μm).

In the HEMT 100, when a large negative voltage is applied to the gate electrode 114, a large depleted layer is formed in the electron transit layer 104 below the gate electrode 114. Consequently current no longer flows between the source electrode 110 and the drain electrode 112. In a state in which a large negative voltage is applied to the gate electrode 114, if the positive voltage applied to the drain electrode 112 is further increased, then at a certain voltage (the off-state breakdown voltage), an electron avalanche phenomenon occurs, a large current flows between the source electrode 110 and the drain electrode 112, and breakdown of the HEMT 100 occurs.

Because in a conventional HEMT 100 this off-state breakdown voltage is low, at 50 V approximately, a large voltage cannot be applied to the drain electrode 112, and as a result there is the problem that large output power cannot be obtained.

### SUMMARY OF THE INVENTION

This invention was devised in light of the above problem, and so an object of this invention is to provide a wafer for semiconductor device fabrication, a method of manufacturing the wafer, and a field effect transistor, for which a large output power can be obtained by raising the off-state breakdown voltage above that of the prior art.

In order to attain the above object, a wafer for semiconductor device fabrication according to a first aspect of the invention comprises a substrate, electron transit layer, and electron supply layer. The electron transit layer is of GaN, and is formed on the principal-surface side of the substrate. The electron supply layer is of AlGaN, and is formed on top of the electron transit layer. The thickness of the electron transit layer is from 0.2 to 0.9 μm.

In a wafer for semiconductor device fabrication in the first aspect of the invention, by making the thickness of the electron transit layer thinner, at 0.2 to 0.9 μm, than in the conventional technology (2 to 3 μm), when a wafer for semiconductor device fabrication of this invention is used to fabricate a field effect transistor, the current which bypasses the depletion layer to flow between source and drain can be made small. By this means, the off-state breakdown voltage can be raised.

In the above-described wafer for semiconductor device fabrication, it is preferable that SiC, sapphire, or Si may be used as the substrate.

By this means, a field effect transistor with a high off-state breakdown voltage can be fabricated on SiC substrate, sapphire substrate, or Si substrate.

Further, in the above-described wafer for semiconductor device fabrication, it is preferable that an AlN layer, or, a GaN layer grown at a temperature lower than the growth temperature of the electron transit layer, may be formed between the substrate and the electron transit layer as a buffer layer.

By this means, a buffer layer which is either an AlN layer, or a layer of GaN grown at a temperature below that of the electron transit layer, functions as a seed crystal to induce growth of the electron transit layer (GaN) on the substrate, so that the electron transit layer can easily be grown on the substrate.

The method for manufacturing a wafer for semiconductor device fabrication according to a second aspect of this invention is the above-described method of manufacture of a wafer for semiconductor device fabrication, comprising the steps of: growing a buffer layer on the principal surface of the substrate; growing the electron transit layer to a thickness of 0.2 to 0.9 μm on the buffer layer; and growing the electron supply layer on top of the electron transit layer.

By means of the method for manufacturing a wafer for semiconductor device fabrication of the second aspect of the invention, a wafer for semiconductor device fabrication having an electron transit layer of thickness 0.2 to 0.9 μm, thin compared with the prior art (2 to 3 μm), can be manufactured. As a result, the off-state breakdown voltage of a field effect transistor fabricated on this wafer for semiconductor device fabrication can be increased.

A field effect transistor according to a third aspect of this invention comprises a gallium nitride compound semiconductor, formed on the above-described wafer for semiconductor device fabrication.

By means of the field effect transistor of the third aspect of the invention, a field effect transistor can be obtained with a high off-state breakdown voltage compared with the prior art.

By means of a wafer for semiconductor device fabrication, manufacturing method therefor, and field effect transistor of this invention, the off-state breakdown voltage of a GaN field effect transistor can be made even higher than in the prior art. As a result, a larger output power can be obtained than was previously possible.

### BRIEF DESCRIPTION OF THE DRAWINGS

The foregoing and other objects, features and advantages of the present invention will be better understood from the following description taken in connection with the accompanying drawings, in which:

FIG. 1 is a schematic cross-sectional view of the cross-sectional structure of a HEMT of a first embodiment of a field effect transistor according to this invention;

FIG. 2 is a diagram for explaining the relation between the drain voltage and the drain current for the HEMT shown in FIG. 1;

FIG. 3 is a sectional view for explaining the basic operation of the HEMT of FIG. 1;

FIG. 4A through FIG. 4C show I-V characteristics for explaining specific operation of the HEMT of FIG. 1;

FIG. 5A through FIG. 5C diagrams for explaining the off-state breakdown voltage of the HEMT of FIG. 1;

FIG. 6 is a diagram for explaining the relation between film thickness and off-state breakdown voltage for the HEMT of FIG. 1;

FIG. 7A and FIG. 7B are sectional views of structures formed respectively at the stages of main processes, to explain the processes of manufacture of the HEMT of FIG. 1;

FIG. 8A and FIG. 8B are sectional views of structures formed respectively at the stages of main processes following that of FIG. 7B, to explain the processes of manufacture of the HEMT of FIG. 1;

FIG. 9 is a sectional view showing the cross-sectional structure of a second embodiment of a wafer for semiconductor device fabrication, which can be applied to the HEMT of FIG. 1; and,

FIG. 10 is a sectional view for explaining a conventional GaN HEMT.

### DESCRIPTION OF THE PREFERRED EMBODIMENTS

With reference to drawings, the invention will be explained hereinbelow. Incidentally, the drawings to be referred show merely schematic of the respective constitutional elements on such a level that the invention can be understood. And materials and the numerical conditions explained below are merely reference examples.

### First Embodiment

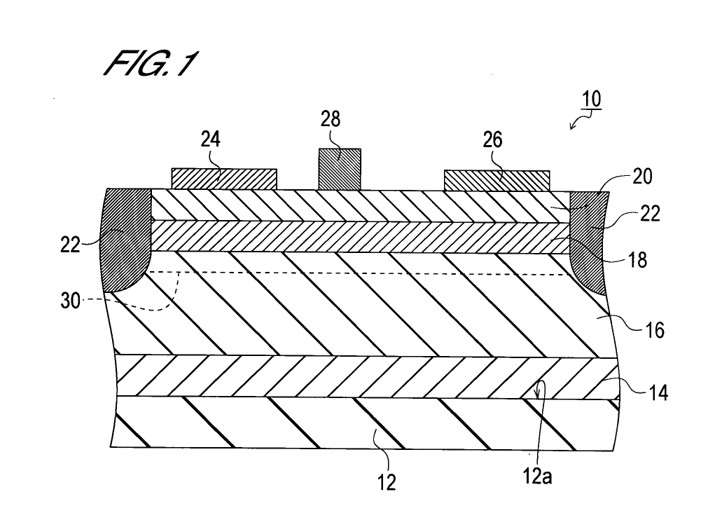

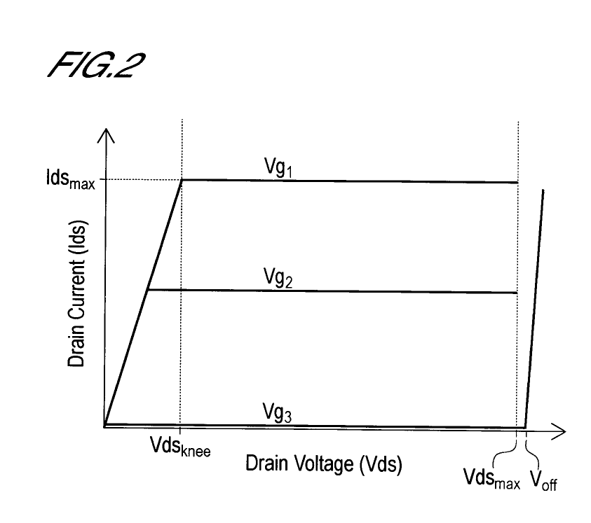

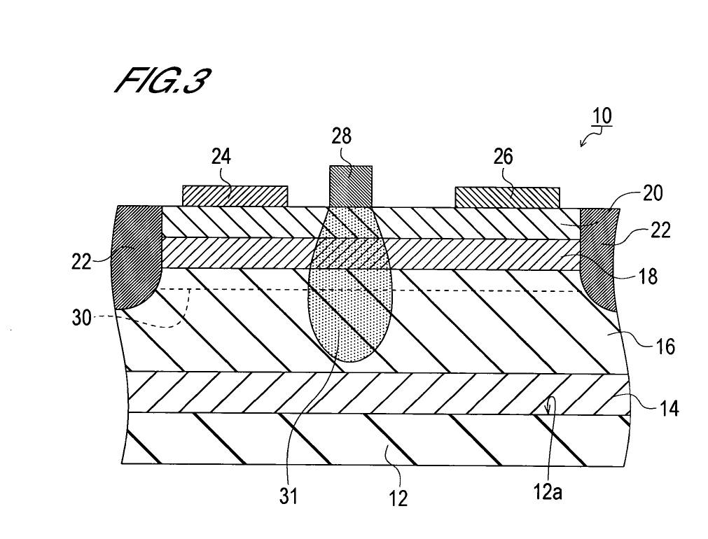

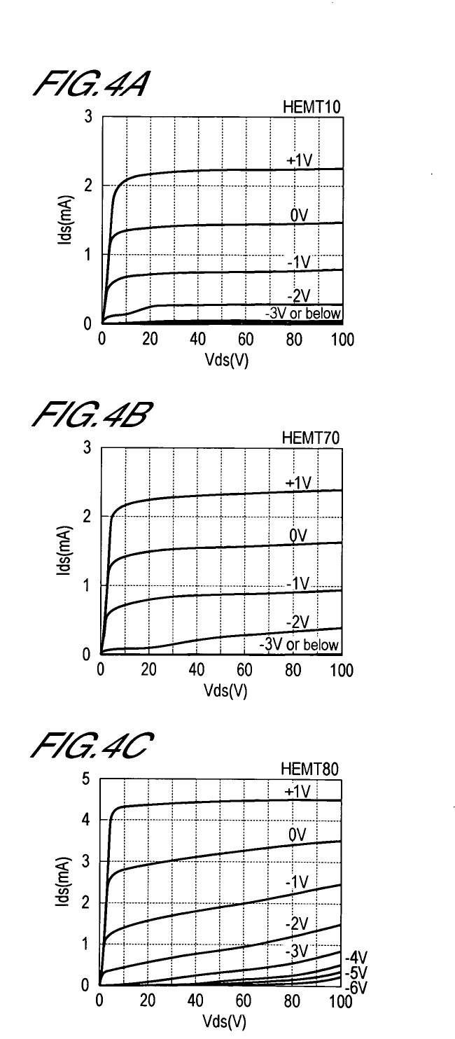

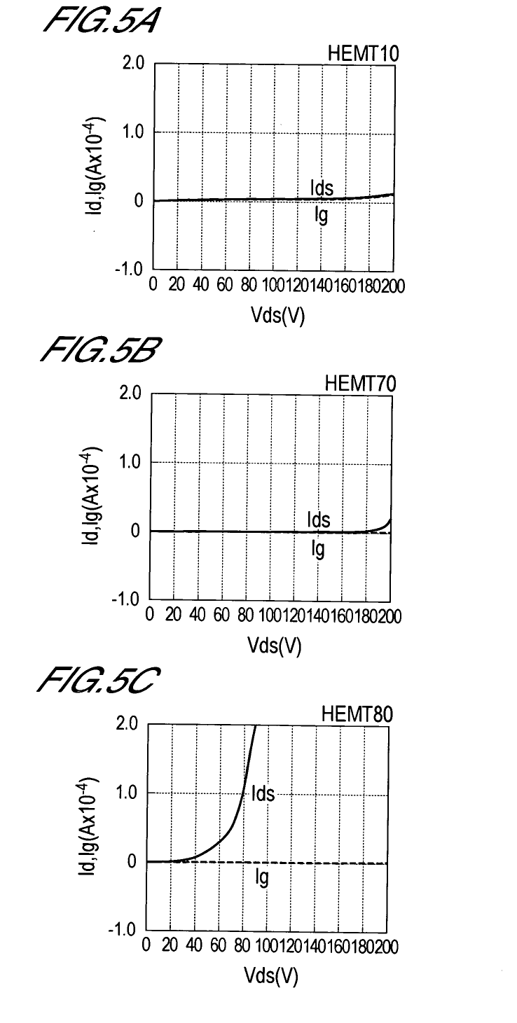

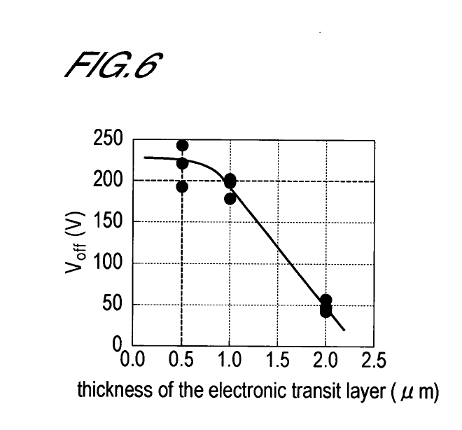

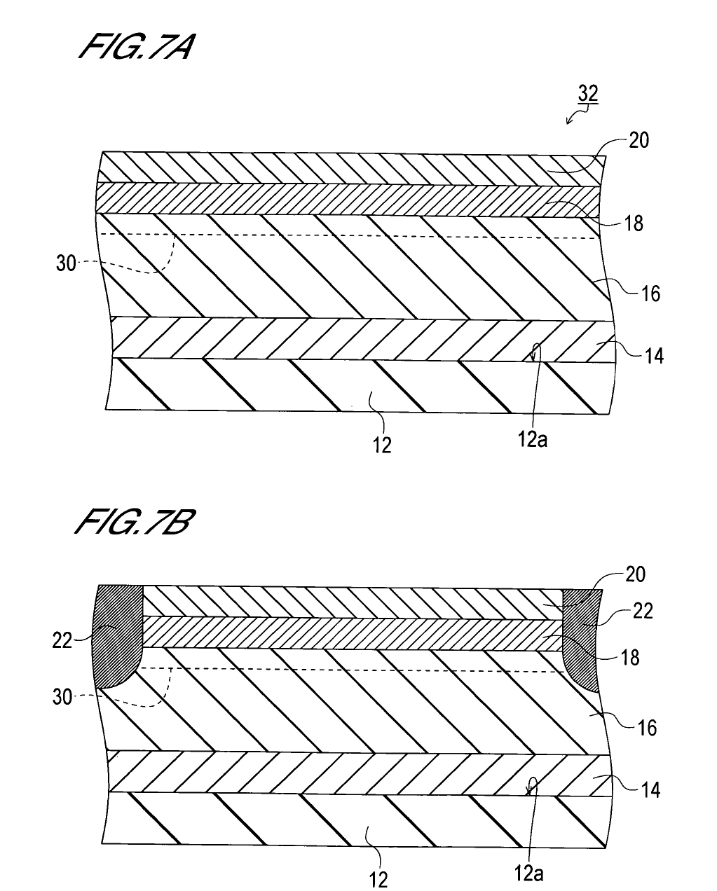

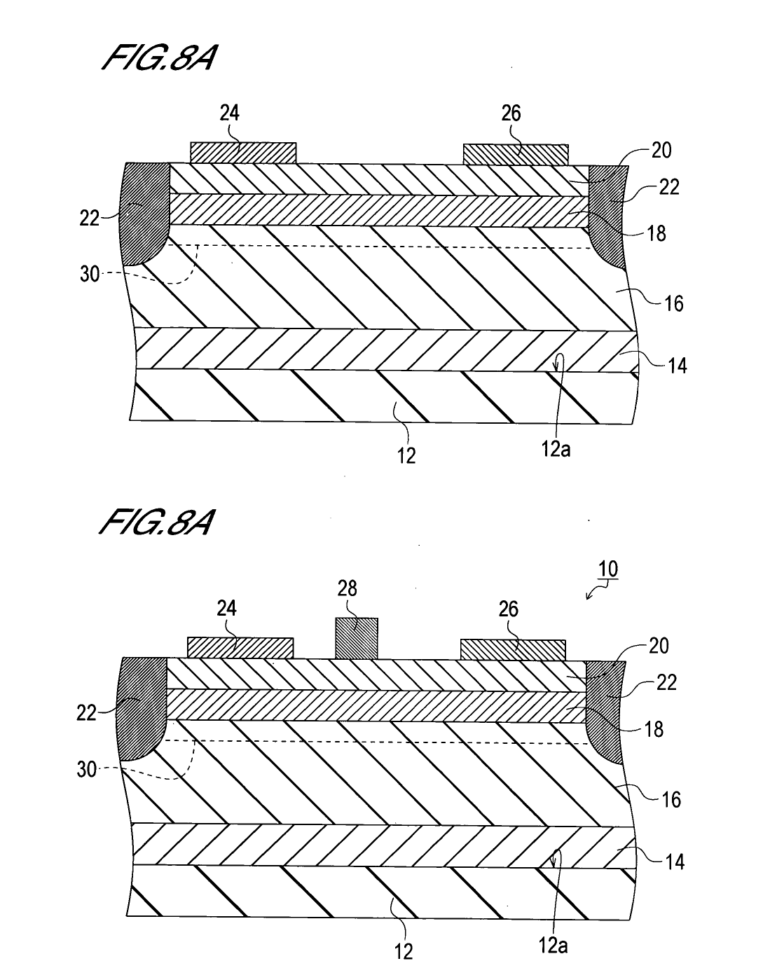

The structure and operation of the HEMT of a first embodiment are explained referring to FIG. 1 through FIG. 8. FIG. 1 is a schematic sectional view showing the cross-sectional structure of the HEMT. FIG. 2 shows the relation between the drain voltage and drain current (hereafter called the “I-V characteristic”). FIG. 3 shows a cross-section used to explain basic operation of the HEMT. FIG. 4A through FIG. 4C show I-V characteristics used to explain the specific operation of the HEMT. FIG. 5A through FIG. 5C are used to explain the off-state breakdown voltage of the HEMT. FIG. 6 shows the relation between film thickness and off-state breakdown voltage for the HEMT. FIG. 7A and FIG. 7B show cross-sections obtained at respective stages of main processes, to explain the processes of manufacture of the HEMT. FIG. 8A and FIG. 8B show cross-sections obtained at respective stages of main processes, to explain the processes of manufacture of the HEMT.

The configuration example shown in FIG. 1 will be explained. The HEMT 10 comprises a substrate 12, buffer layer 14, electron transit layer 16, electron supply layer 18, cap layer 20, and element isolation layers 22, 22.

The substrate 12 is of semi-insulating SiC crystal. The buffer layer 14 is formed on the principal surface 12a of the substrate 12.

The buffer layer 14 is of AlN, and is grown at a temperature of approximately 1100° C. using an MOCVD (metallorganic chemical vapor deposition) method on the principal surface 12a of the substrate 12. It is preferable that the buffer layer 14 may be, for example, approximately 100 nm thick; but the thickness can be set to an arbitrary appropriate value in the range 10 to 200 nm according to the design.

The electron transit layer 16 is of undoped GaN, and is grown on the buffer layer 14 by the MOCVD method at a temperature of approximately 1070° C. It is preferable that the electron transit layer 16 may be for example 0.5 μm thick, or with thickness in the range 0.2 to 0.9 μm, but the thickness can be set arbitrarily as appropriate according to the design, taking into account the off-state breakdown voltage V_{off} and similar. It is known that, for reasons pertaining to manufacture, the thickness of the electron transit layer 16 inevitably comprises an error with respect to a growth target thickness of at most ±20% approximately. Hence “a thickness for the electron transit layer 16 of 0.2 to 0.9 μm” should be taken to mean that the thickness of the electron transit layer 16, including the above-described error (±20%), is between 0.2 and 0.9 μm.

The electron supply layer 18 is of undoped Al_{0.25}Ga_{0.75}N, and is grown on the electron transit layer 16 at a temperature of approximately 1070° C. by the MOCVD method. It is preferable that the electron supply layer 18 may be for example 20 nm thick, but the thickness can be set arbitrarily as appropriate to the design in the range 10 to 40 nm.

At the heterointerface between the electron transit layer 16 (GaN) and the electron supply layer 18 (Al_{0.25}Ga_{0.75}N), due to the piezoelectric effect arising from lattice mismatching, electrons are generated and accumulate in the electron transit layer 16 near the heterointerface (within approximately 10 nm), and a two-dimensional electron layer 30 is formed by these electrons.

The cap layer 20 is of undoped GaN, and is grown on the electron supply layer 18 at a temperature of approximately 1070° C. by the MOCVD method. The cap layer 20 has the function of a protective layer for the electron supply layer 18. It is preferable that the cap layer 20 may be of thickness 5 nm, for example, but the thickness can be set arbitrarily as appropriate, according to the design.

On the cap layer 20, a source electrode 24 and drain electrode 26 are provided, separated from each other, via an Ohmic junction with the cap layer 20. Between the source electrode 24 and drain electrode 26 is provided a gate electrode 28, which is spaced from the source electrode 24 and the drain electrode 26 and forming a Schottky junction with the cap layer 20. Here it is preferable that the gate length of the HEMT 10, that is, the length of the gate electrode 28 in the lateral direction in FIG. 1, may be for example 1 μm. It is preferable that the gate width, that is, the length of the gate electrode 28 in the vertical direction in FIG. 1, may be for example 10 μm.

Element isolation layers 22, 22 to electrically separate the HEMT 10 from other adjacent elements are at a distance from the source and drain electrodes 24 and 26 respectively, and provided so as to enclose the source and drain electrodes 24 and 26. The element isolation layers 22, 22 are formed by implanting Ar ions and Cr ions from the surface of the cap layer 20 throughout a depth greater than that of the two-dimensional electron layer 30. By this means, the crystal structure in the cap layer 20, electron supply layer 18 and electron transit layer 16 is destroyed, and the ion implantation region becomes insulating.

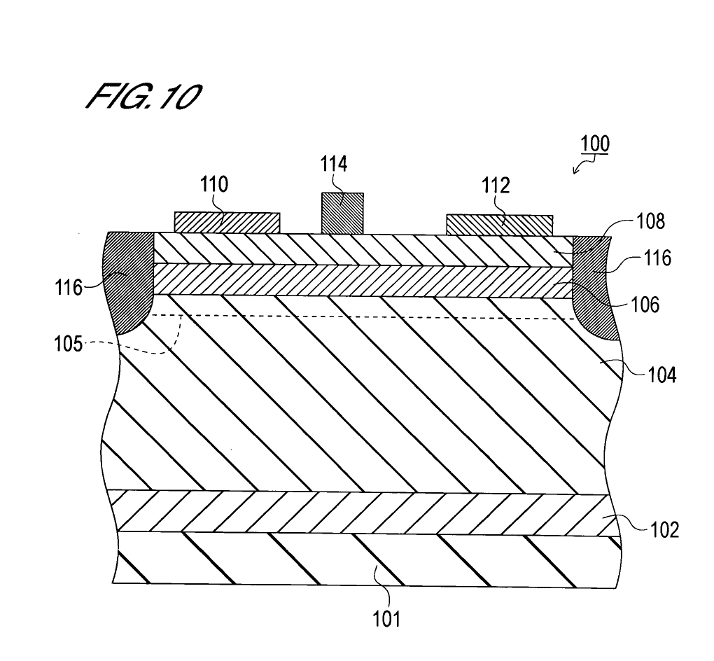

In the above, the structure of the HEMT 10 has been explained; the HEMT 10 shown in FIG. 1 has the same structure as the conventional HEMT 100 shown in FIG. 10, except for the fact that the thickness of the electron transit layer 16 is 0.5 μm.

Next, the basic operation of the HEMT 10 will be explained, referring to FIG. 2 and FIG. 3.

FIG. 2 schematically shows the relation between the drain voltage Vds (horizontal axis) and drain current Ids (vertical axis) (hereafter called the “I-V characteristic”), when the voltage Vg applied to the gate electrode 28 (hereafter also called the “gate voltage”) is varied between the three values Vg₁, Vg₂ and Vg₃, the source electrode 24 is grounded, and the positive voltage Vds applied to the drain electrode 26 (hereafter also called the “drain voltage”) is varied. Here, Vg₁>Vg₂>Vg₃, and in particular, Vg₃ is a large negative voltage (for example, −6 V).

At this time, the gate voltage Vg is increased, and the drain current Ids increases. The maximum value of the drain current Ids at gate voltage Vg₁, that is, the value of the drain current Ids when the drain current Ids becomes constant, is Idsₘₐₓ. The minimum value of the drain voltage Vds resulting in Idsₘₐₓ, that is, the drain voltage Vds at the inflection point of the graph for Vg₁, is the knee voltage Vdsₖₙₑₑ.

When the gate voltage Vg is changed, the following phenomenon occurs in the HEMT 10. Upon changing the gate voltage Vg, a depletion layer 31 (see FIG. 3) in which electrons cannot exist is formed in the portion below the gate electrode 28. As the voltage Vg applied to the gate electrode 28 increases from negative to positive, this depletion layer 31 shrinks. As the depletion layer 31 shrinks, electrons move more easily in the electron transit layer 16. That is, the drain current Ids increases.

A case in which a large negative voltage Vg₃ is applied to the gate electrode 28 will be examined. In this case, as shown in FIG. 3, the depletion layer 31 broadens to a region deeper than the two-dimensional electron layer 30. Because of this depletion layer 31, the flow of electrons from the source electrode 24 to the drain electrode 26 is blocked. Hence as shown by the graph for Vg₃ in FIG. 2, there is almost no drain current Ids even when the drain voltage Vds is increased.

However, upon exceeding the off-state breakdown voltage V_{off}, which is a prescribed drain voltage Vds, an electron avalanche phenomenon occurs. As a result, the number of electrons increases as they bypass the depletion layer 31, and flow at once from the source electrode 24 to the drain electrode 26. That is, as shown in the graph for Vg₃ in FIG. 2, in the region of drain voltages Vds equal to or above V_{off}, the drain current Ids suddenly begins to increase.

In general, the off-state breakdown voltage V_{off} is defined as the drain voltage Vds at which a drain current Ids of 1 μA is detected, converted into units per 1 μm gate width, in a state in which a large negative voltage is applied to the gate electrode 28.

Further, the drain voltage Vds which is slightly lower than the off-state breakdown voltage V_{off}, that is, the drain voltage just before the occurrence of the electron avalanche phenomenon, is Vdsₘₐₓ (V_{off}>Vdsₘₐₓ). At this time, the output power from the drain electrode 26 can be approximately represented by (Vdsₘₐₓ−Vdsₖₙₑₑ)×Idsₘₐₓ/8. Here, it is seen that when the knee voltage Vdsₖₙₑₑ and the maximum value Idsₘₐₓ of the drain current are constant, in order to increase the output power, it is effective to increase the Vdsₘₐₓ, that is, the off-state breakdown voltage V_{off}.

Next, FIG. 4A to FIG. 4C, FIG. 5A to FIG. 5C and FIG. 6 are referenced to explain the basic operation of the HEMT 10.

Here, in order to clarify the features of the HEMT 10 of this embodiment, a HEMT 70 and HEMT 80 with structure similar to that of the HEMT 10 except for the thickness of the electron transit layer 16 were fabricated. The thickness of the electron transit layer 16 in the HEMT 70 was 1.0 μm; the thickness of the electron transit layer 16 in the HEMT 80 was 2.0 μm. The HEMTs 70 and 80, with electron transit layers 16 of thickness greater than 0.9 μm, are equivalent to the technology of the prior art.

FIG. 4A through FIG. 4C show I-V characteristics of the HEMTs 10, 70 and 80 respectively. In FIG. 4, the vertical axis plots the drain current Ids (mA), and the horizontal axis plots the drain voltage Vds (V). The figures appended to each of the graphs indicate the voltages applied to the gate electrodes 28, that is, the gate voltage Vg. Here, the gate voltage Vg was varied in 1 V intervals from +1 V to −6 V.

According to FIG. 4C, in the HEMT 80 with an electron transit layer 16 of thickness 2.0 μm, a drain current Ids begins to flow from a Vds of approximately 50 V, even when a large negative voltage (for example −6 V) is applied to the gate electrode 28. That is, the off-state breakdown voltage V_{off} of the HEMT 80 is approximately 50 V.

On the other hand, in the HEMTs 10 and 70 with the I-V characteristics shown in FIG. 4A and FIG. 4B respectively, when a large negative voltage (for example −6 V) is applied to the gate electrode 28, the drain current Ids is substantially 0 A within the Vds measurement range (0 to 100 V).

FIG. 5A to FIG. 5C show measured results for the off-state breakdown voltage V_{off} of the HEMTs 10, 70, 80 respectively. In FIG. 5, the vertical axis indicates the drain current Ids (A) and the gate current Ig (A), and the horizontal axis indicates the drain voltage Vds (V). Of the two curves shown in each graph, the dashed lines represent the gate current Ig, and the solid lines represent the drain current Ids.

In FIG. 5, the gate current Ig is plotted in addition to the drain current Ids in order to clarify the contribution to the drain current Ids of the current flowing from the source electrode 24 to the drain electrode 26. That is, the drain current Ids is the sum of (i) the current flowing from the source electrode 24 to the drain electrode 26, and (ii) the current flowing from the gate electrode 28 to the drain electrode 26 (the gate current Ig). In other words, in order to accurately determine the magnitude of the current flowing from the source electrode 24 to the drain electrode 26, the gate current Ig must be subtracted from the drain current Ids. That is, in FIG. 5, the difference between the drain current Ids and the gate current Ig represents the magnitude of the current flowing from the source electrode 24 to the drain electrode 26.

In the measurements of FIG. 5A through FIG. 5C, the gate voltage Vg is in all cases −6 V.

According to FIG. 5C, in the HEMT 80 the gate current Ig is substantially 0 A, regardless of the drain voltage Vds. On the other hand, the drain current Ids begins to increase sharply from a drain voltage Vds of approximately 40 V. That is, from near 40 V the electron avalanche phenomenon causes the current flowing from the source electrode 24 to the drain electrode 26 to increase.

As stated above, the off-state breakdown voltage V_{off} is defined as the drain voltage Vds at which a 1 μA drain current Ids is detected, per 1 μm of gate width. According to this definition, in a HEMT 80 with a gate width of 10 μm, the drain voltage Vds at which a 10 μA drain current Ids flows is the off-state breakdown voltage V_{off}. Hence from FIG. 5C, the off-state breakdown voltage V_{off} for the HEMT 80 is determined to be approximately 46 V.

As explained above, when a large negative gate voltage Vg is applied, a depletion layer 31 deeper than the two-dimensional electron layer 30 is formed in the electron transit layer 16 below the gate electrode 28. The drain current Ids occurring due to the electron avalanche phenomenon is due to electrons which move in the electron transit layer 16 below the depletion layer 31, so as to bypass the depletion layer 31. That is, in the HEMT 80, even if a large depletion layer 31 is formed in the electron transit layer 16 below the gate electrode 28, because the electron transit layer 16 is thick, electrons move through the electron transit layer 16 below the depletion layer 31, bypassing the depletion layer 31. This is the cause of the small off-state breakdown voltage V_{off} of the HEMT 80.

According to FIG. 5B, in the HEMT 70, the drain current Ids is substantially 0 A until the drain voltage Vds reaches approximately 180 V. From a drain voltage Vds of approximately 180 V, an increase in the drain current Ids is seen. By a method similar to that used for FIG. 5C, the off-state breakdown voltage V_{off} for the HEMT 70 is found from FIG. 5B to be approximately 178 V.

According to FIG. 5A, in the HEMT 10, the drain current Ids increases slightly from a drain voltage Vds of approximately 130 V. However, in addition to the drain current Ids, the gate current Ig is also increasing, and so it is inferred that the increase in the drain current Ids is due not to an electron avalanche phenomenon, but to an increase in the gate current Ig. In accordance with the above-described definition, the off-state breakdown voltage V_{off} of the HEMT 10 is found, from FIG. 5A, to be approximately 193 V.

Thus the reason for the higher off-state breakdown voltage V_{off} obtained from the HEMT 10 than in the prior art is the fact that the electron transit layer 16 is thinner than in the prior art. That is, in the HEMT 10 with a thin (0.5 μm) electron transit layer 16, the depletion layer 31 extends to a depth equal to the thickness of the electron transit layer 16 (0.5 μm), so that the region through which electrons can move is narrowed. As a result, even if a high drain voltage Vds is applied, it is difficult for electrons to move bypassing the depletion layer 31. As a result, the off-state breakdown voltage V_{off} is increased.

Table 1 shows the characteristics of two-dimensional electrons existing in the two-dimensional electron layer 30 in the HEMTs 10, 70 and 80, respectively. The two-dimensional electron characteristics shown in Table 1 were measured using a Van der Pol type Hall effect measurement instrument.

TABLE 1

| | | Two- | Two- | |
|---|---|---|---|---|
| | Thickness | dimensional | dimensional | |
| | of electron | electron | electron | Sheet |
| | transit layer | mobility | concentration | resistance |
| | (μm) | (cm²/Vs) | (×10¹³ cm⁻²) | (Ω/□) |
| HEMT10 | 0.5 | 1670 | 0.71 | 530 |
| HEMT70 | 1.0 | 1740 | 0.66 | 547 |
| HEMT80 | 2.0 | 1600 | 1.00 | 389 |

From Table 1, as the thickness of the electron transit layer 16 is reduced, that is, in moving from the HEMT 80 to the HEMT 10, a tendency is seen for the two-dimensional electron mobility and the two-dimensional electron concentration to be reduced. However, in the HEMT 10 with a thickness of the electron transit layer 16 of 0.5 μm, a two-dimensional electron concentration and two-dimensional electron mobility sufficient for operation of a high-speed mobility transistor (HEMT) are retained.

FIG. 6 shows the relation between the thickness of the electron transit layer 16 (horizontal axis) and the off-state breakdown voltage V_{off}(vertical axis), in nine types of HEMT which, other than variously modifying the thickness of the electron transit layer 16, have structures similar to that of the HEMT 10. In FIG. 6, points corresponding to the HEMTs 10, 70, and 80 are also plotted.

According to FIG. 6, as the thickness of the electron transit layer 16 is reduced, the off-state breakdown voltage V_{off} rises. That is, the off-state breakdown voltage V_{off} for a HEMT with an electron transit layer 16 of thickness 2.0 μm is approximately 50 V. The off-state breakdown voltage V_{off} for a HEMT with an electron transit layer 16 of thickness 1.0 μm is approximately 180 V. And, the off-state breakdown voltage V_{off} for a HEMT of this invention, with an electron transit layer 16 of thickness 0.5 μm, is approximately 220 V on average.

Next, a method of fabrication of a HEMT 10 will be explained with reference to FIG. 7A and FIG. 7B and to FIG. 8A and FIG. 8B.

First, a substrate 12 of semi-insulating SiC crystal, of thickness approximately 300 μm, is prepared.

A buffer layer 14 of AlN is grown by the MOCVD to a thickness of approximately 100 nm on the principal surface 12a of the substrate 12, at a temperature of approximately 1100° C.

An electron transit layer 16 of undoped GaN is grown by the MOCVD method to a thickness of approximately 0.5 μm on the buffer layer 14, at a temperature of approximately 1070° C.

An electron supply layer 18 of undoped Al_{0.25}Ga_{0.75}N is grown by the MOCVD method to a thickness of approximately 20 nm on the electron transit layer 16, at a temperature of approximately 1070° C.

A cap layer 20 of undoped GaN is grown by the MOCVD method to a thickness of approximately 5 nm on the electron supply layer 18, at a temperature of approximately 1070° C.

In this way, a wafer 32 for semiconductor device fabrication is obtained (see FIG. 7A), in which a two-dimensional electron layer 30 is formed in the electron transit layer 16 near the heterointerface between the electron transit layer 16 and the electron supply layer 18.

Element isolation layers 22, 22, to electrically separate the HEMT 10 from other elements, are formed in the wafer 32. Specifically, regions other than the regions planned for formation of the element isolation layers 22, 22 are covered with photoresist or some other film for protection from ion implantation, and then Ar ions are implanted to a depth exceeding the depth of the two-dimensional electron layer 30. Thereafter, a well-known method is used to remove the ion implantation protection film. By this means, the crystal structure of the cap layer 20, electron supply layer 18, and electron transit layer 16 is destroyed in the regions in which ions have been implanted, rendering these regions insulating, and forming the element isolation layers 22, 22 (see FIG. 7B).

The source electrode 24 and drain electrode 26 are fabricated. Specifically, a photolithography technique is used to cover regions other than the regions planned for formation of the source electrode 24 and drain electrode 26 with photoresist. Then, Ti is vacuum-deposited to approximately 15 nm, and Al is deposited to approximately 200 nm, in this order. Following this, a lift-off method is used to remove the photoresist and also unwanted Ti and Al, leaving an Al/Ti stacked structure only in regions corresponding to the source electrode 24 and drain electrode 26. Then heat treatment is performed for two to three minutes at a temperature of approximately 700° C., to obtain a source electrode 24 and drain electrode 26 with Ohmic junctions with the cap layer 20 (see FIG. 8A).

The gate electrode 28 is fabricated. Specifically, a photolithographic technique is used to cover regions excluding the region planned for formation of the gate electrode 28 with photoresist. On top of this are vacuum-deposited Ni to approximately 50 nm and Au to approximately 500 nm, in this order. Then, a lift-off method is used to remove the photoresist as well as unwanted Ni and Au, leaving an Au/Ni stacked structure only in the region corresponding to the gate electrode 28. Thereafter heat treatment is performed for two to three minutes at a temperature of approximately 700° C., to obtain a gate electrode 28 with a Schottky junction with the cap layer 20 (see FIG. 8B).

By this means, the HEMT 10 is obtained.

In this way, the thickness of the electron transit layer 16 of the HEMT 10 of this embodiment is thinner, at 0.2 to 0.9 μm, than in the prior art (2 to 3 μm). Consequently, the quantity of electrons which move between source and drain bypassing the depletion layer 31 can be reduced. As a result, the off-state breakdown voltage V_{off} of the GaN HEMT 10 is raised. Specifically, the off-state breakdown voltage V_{off} of a HEMT 10 with an electron transit layer 16 of thickness 0.5 μm is 193 V. This value is approximately four times that for a conventional HEMT 80, the thickness of the electron transit layer 16 of which is 2.0 μm. The value is also approximately 15 V higher than that of a HEMT 70 with an electron transit layer 16 of thickness 1.0 μm. Thus the HEMT 10 has a higher off-state breakdown voltage V_{off} than in the prior art, so that larger output power can be obtained than in the prior art.

In the HEMT 10 of this embodiment, a GaN high-speed mobility transistor with high off-state breakdown voltage V_{off} can be fabricated on a substrate 12 of SiC crystal.

The HEMT 10 of this embodiment is provided with a buffer layer 14 of AlN between the principal surface 12a of the substrate 12 and the electron transit layer 16, so that the buffer layer 14 functions as a seed crystal inducing growth of the electron transit layer 16 (GaN) on the substrate 12, and the electron transit layer 16 can easily be grown on the principal surface 12a of the substrate 12.

The method of manufacture of the HEMT 10 of this embodiment is similar to methods of manufacture of the prior art, other than the reduced thickness of the electron transit layer 16. Hence existing manufacturing lines can be utilized in manufacture of such HEMTs 10 without adding modifications. Further, the electron transit layer 16 is made thinner than in the prior art, so that the time required for growth of the electron transit layer 16 can be shortened, and as a result the throughput for manufacture of the HEMT 10 can be improved.

Moreover, a wafer 32 for semiconductor device fabrication of this embodiment is used, so that a GaN HEMT 10 with higher off-state breakdown voltage V_{off} than in the prior art can be obtained.

In this embodiment, the thickness of the electron transit layer 16 is 0.2 to 0.9 μm; but it is still more preferable that the thickness of the electron transit layer 16 may be 0.3 to 0.9 μm.

If the thickness of the electron transit layer 16 is 0.3 μm or greater, an adequate two-dimensional electron concentration and adequate two-dimensional electron mobility in the two-dimensional electron layer 30 are obtained to enable functioning as a HEMT. If the thickness of the electron transit layer 16 is in the range 0.2 μm or greater but less than 0.3 μm, a two-dimensional electron concentration and two-dimensional electron mobility in the two-dimensional electron layer 30 enabling practical use are obtained, although performance is inferior to the case of an electron-transit layer thickness of 0.3 μm or greater. According to TEM (transmission electron microscopy) observations by the inventors, when the thickness of the electron transit layer 16 is less than 0.2 μm, numerous penetrating dislocations and other crystal defects occurring from the interface between the buffer layer 14 (AlN) and the electron transit layer 16 (GaN) exist in the electron transit layer 16, which is undesirable.

It is also preferable that the thickness of the electron transit layer 16 may be of thickness 0.9 μm or less. By making the thickness of the electron transit layer 0.9 μm or less, an off-state breakdown voltage V_{off} of approximately 200 V or greater can be obtained, as shown in FIG. 6.

In this embodiment, SiC is used as the substrate 12; but a sapphire substrate or Si substrate may be used.

The buffer layer 14 is not limited to AlN, and a low-temperature buffer layer of undoped GaN, grown by MOCVD at a comparatively low temperature (approximately 475° C.), may be used.

The Al_{0.25}Ga_{0.75}N of the electron supply layer 18 may be doped with Si as an impurity to a concentration of from 1×10¹⁷ to 5×10¹⁸ atoms/cm³, using a well-known method.

### Second Embodiment

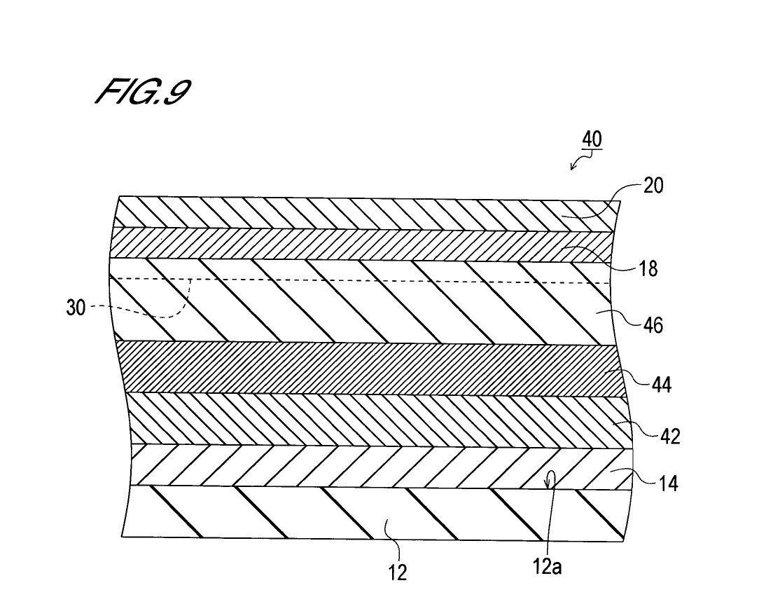

The structure and operation of a wafer for semiconductor device fabrication of a second embodiment are explained, referring to FIG. 9. FIG. 9 is a schematic sectional view showing the cross-sectional structure of a second embodiment of the wafer for semiconductor device fabrication.

The wafer 40 for semiconductor device fabrication of the second embodiment has the same structure as the wafer 32 for semiconductor device fabrication explained in the first embodiment, except for two differences, which are the provision, on the buffer layer 14, of an AlGaN layer as a second buffer layer 42, and the provision, on the second buffer layer 42, of a superlattice 44 in which AlN layers and GaN layers are stacked in alternation. Here, the same symbols are assigned to constituent components common to the wafer 32 for semiconductor device fabrication, and explanations thereof are omitted.

The wafer 40 for semiconductor device fabrication comprises a substrate 12, of semi-insulating SiC crystal; a buffer layer 14; a second buffer layer 42; a superlattice 44; an electron transit layer 46; an electron supply layer 18; and a cap layer 20.

Similarly to the first embodiment, the substrate 12 is semi-insulating SiC crystal.

Other than being of thickness 8 nm, the buffer layer 14, having the same composition (AlN) as in the first embodiment, is grown in a manner similar to the first embodiment on the principal surface 12a of the substrate 12.

The second buffer layer 42 is of undoped AlGaN, and is grown on the buffer layer 14 by the MOCVD method at a temperature of approximately 1070° C. It is preferable that the second buffer layer 42 may be for example of thickness 40 nm, but the thickness can be selected arbitrarily as appropriate to the design.

The superlattice 44 has a stacked structure in which a layering unit of 5 nm undoped AlGaN grown on 20 nm undoped GaN is one period, and 20 such periods of layering units are stacked. This superlattice 44 is grown by a well-known MOCVD method.

The electron transit layer 46 has the same composition and thickness as in the first embodiment, and is formed similarly to that in the first embodiment.

The electron supply layer 18 has the same composition and thickness as in the first embodiment, and is formed similarly to that in the first embodiment.

The cap layer 20 has the same composition and thickness as in the first embodiment, and is formed similarly to that in the first embodiment.

Thus by using a wafer 40 for semiconductor device fabrication of this second embodiment to manufacture a GaN HEMT, similarly to the HEMT 10 of the first embodiment, a HEMT with a higher off-state breakdown voltage V_{off} than in the prior art can be obtained.

Further, the wafer 40 for semiconductor device fabrication of this second embodiment comprises a second buffer layer 42 and a superlattice 44, so that these layers 42 and 44 effectively absorb mismatching of the lattice constants of the crystal lattice between the substrate 12 and the electron transit layer 46. As a result, the crystallinity of the electron transit layer 46 can be improved compared with the electron transit layer 16 of the first embodiment.

That is, when performing a comparison for the same thickness, the electron transit layer 46 of the second embodiment has fewer crystal defects, and better crystallinity, than the electron transit layer 16 of the first embodiment. Hence when comparing the same thickness, two-dimensional electrons are generated and accumulated at higher concentrations, and the mobility of accumulated two-dimensional electrons is higher, in the two-dimensional electron layer 30 of the electron transit layer 46, compared with the two-dimensional electron layer 30 of the electron transit layer 16 of the first embodiment.

In other words, in order to reach a two-dimensional electron concentration and two-dimensional electron mobility equivalent to those of the first embodiment, the electron transit layer 46 of the second embodiment can be made even thinner than the electron transit layer 16 of the first embodiment. Hence the wafer 40 for semiconductor device fabrication of the second embodiment can attain a higher off-state breakdown voltage V_{off}, while maintaining a two-dimensional electron concentration and two-dimensional electron mobility equivalent to those of the wafer 32 for semiconductor device fabrication of the first embodiment.

In this second embodiment, as the stacking unit comprised by the superlattice 44, 5 nm of AlGaN grown on top of 20 nm of GaN is used; but there are no limitations in particular on the thicknesses of the GaN and AlGaN, or on the ratio of thicknesses, and the thicknesses and ratio of thicknesses can be varied arbitrarily as appropriate to the design.

The preferred range for the thickness of the electron transit layer 46 is similar to that explained in the first embodiment.

The type of substrate 12 used in this Aspect 2 can be modified similarly to the first embodiment.

The buffer layer 14 can also be modified similarly to the first embodiment.

The electron supply layer 18 can also be modified similarly to the first embodiment.

What is claimed is:

1. A wafer for semiconductor device fabrication, comprising a substrate, an electron transit layer of GaN formed on the side of the principal surface of said substrate, and an electron supply layer of AlGaN formed on said electron transit layer, wherein
the thickness of said electron transit layer is from 0.2 to 0.9 μm.

2. The wafer for semiconductor device fabrication according to claim 1, wherein the thickness of said electron transit layer is from 0.3 to 0.9 μm.

3. The wafer for semiconductor device fabrication according to claim 1, wherein said electron transit layer comprises undoped GaN.

4. The wafer for semiconductor device fabrication according to claim 1, wherein said electron supply layer comprises Al_{0.25}Ga_{0.75}N.

5. The wafer for semiconductor device fabrication according to claim 4, wherein the thickness of said electron supply layer is from 10 to 40 nm.

6. The wafer for semiconductor device fabrication according to claim 3, wherein said electron supply layer is doped with Si ranging from 1×10¹⁷ to 1×10¹⁸ atoms/cm³.

7. The wafer for semiconductor device fabrication according to claim 1, wherein said substrate is of SiC, sapphire, or Si.

8. The wafer for semiconductor device fabrication according to claim 7, wherein an AlN layer, or a layer comprising GaN grown at a temperature lower than that of the electron transit layer, is formed, as a buffer layer, between said substrate and said electron transit layer.

9. The wafer for semiconductor device fabrication according to claim 8, wherein the thickness of said buffer layer is from 10 to 200 nm.

10. The wafer for semiconductor device fabrication according to claim 1, wherein a cap layer comprising undoped GaN is formed on said electron supply layer.

11. A method for manufacturing a wafer for semiconductor device fabrication according to claim 8, comprising the steps of:
growing said buffer layer on said principal surface of said substrate;
growing said electron transit layer to a thickness of from 0.2 to 0.9 μm on said buffer layer; and
growing said electron supply layer on said electron transit layer.

12. The method for manufacturing a wafer for semiconductor device fabrication according to claim 11, wherein said buffer layer is grown by an MOCVD method at a temperature of 1100° C.

13. The method for manufacturing a wafer for semiconductor device fabrication according to claim 11, wherein said electron transit layer is grown by an MOCVD method at a temperature of 1070° C.

14. The method for manufacturing a wafer for semiconductor device fabrication according to claim 11, wherein said electron supply layer is grown by an MOCVD method at a temperature of 1070° C.

15. A field effect transistor, comprising a gallium nitride compound semiconductor, formed on said wafer for semiconductor device fabrication according to claim 1.

16. The field effect transistor according to claim 15, wherein a source electrode and drain electrode comprise a stacked structure of Ti and Al, stacked in the order of Ti and Al.

17. The field effect transistor according to claim 16, wherein a gate electrode is provided between said source electrode and said drain electrode, and said gate electrode comprises a stacked structure of Ni and Au, stacked in the order of Ni and Au.

18. The field effect transistor according to claim 17, wherein an element isolation layer is spaced from said source electrode and from said drain electrode, so as to enclose a pair comprising said source electrode and said drain electrode.

19. The field effect transistor according to claim 18, wherein said element isolation layer is an ion implantation region of Ar ions or Cr ions.

20. The field effect transistor according to claim 15, wherein, when a voltage of −6 V or lower is applied to the gate electrode, the off-state breakdown voltage is 190 V or higher, where the off-state breakdown voltage is the drain voltage when a 1 μA drain current per micron of gate width is flowing.
